(19) United States
(12) Patent Application Publication
(10) Pub. No.: US 2010/0314714 A1
(43) Pub. Date: Dec. 16, 2010

(54) INTEGRATED CIRCUIT DEVICE

(75) Inventor: Atsushi NAKAMURA, Hyogo (JP)

Correspondence Address: McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/849,583

(22) Filed: Aug. 3, 2010

Related U.S. Application Data
(63) Continuation of application No. PCT/JP2009/002699, filed on Sep. 12, 2008.

(30) Foreign Application Priority Data
Sep. 12, 2008 (JP) 2008-235217

(51) Int. Cl. H01L 23/538

(52) U.S. Cl. 257/531; 257/E23.169

(57) ABSTRACT

An integrated circuit device includes a first substrate and a second substrate. The first substrate includes a semiconductor substrate. An active element portion is formed on one of the surfaces of the first substrate, and a first through electrode electrically connected to the active element is formed to extend through the first substrate. A passive element is formed on one of the surfaces of the second substrate, and a second through electrode electrically connected to the passive element is formed to extend through the second substrate. The other surface of the first substrate and the other surface of the second substrate are opposed to each other, and the first through electrode and the second through electrode are electrically connected to each other.

### CROSS-REFERENCE TO RELATED APPLICATION

This is a continuation of PCT International Application PCT/JP2009-002699 filed on Jun. 15, 2009, which claims priority to Japanese Patent Application No. 2008-235217 filed on Sep. 12, 2008. The disclosures of these applications including the specifications, the drawings, and the claims are hereby incorporated by reference in their entirety.

### BACKGROUND

More single-chip packages are used for monolithic ICs, which have active elements such as transistors and passive elements such as capacitors and inductors integrated on a semiconductor substrate to form circuits such as amplifiers and filters, because the production cost can be reduced, the power consumption can be reduced, and size reduction can be achieved.

However, in formation of an inductor on a semiconductor substrate, there arises a problem of causing parasitic capacitance and parasitic resistance (eddy-current loss) between a conductive material constituting the inductor and the semiconductor substrate. To obtain an inductor with high Q-value, therefore, the parasitic capacitance and the parasitic resistance must be reduced.

As a method for reducing the parasitic capacitance and the parasitic resistance, proposed is producing active elements such as transistors and passive elements such as resistances, capacitors, and inductors on different substrates and then connecting such substrates to each other. This makes it possible to increase the distance between the inductors and the semiconductor substrate, and as a result, reduce the parasitic capacitance and the parasitic resistance.

In recent years, attention has been focused on system-in-package technology in which a plurality of semiconductor chips including integrated circuits are densely packaged to implement a high-function system in a short time, and various manufacturers have proposed a variety of packaging structures. In particular, development of multilayer packages is being actively pursued in which a plurality of semiconductor chips are stacked three-dimensionally to achieve substantial size reduction.

Among methods for stacking a plurality of semiconductor chips three-dimensionally for packaging, a method using wire bonding is the mainstream. In this method, however, it is predicted that the length of interconnection may produce a bottleneck against high-speed transmission and that the necessity to secure the bonding area may produce a bottleneck against reduction in size and thickness. For this reason, a method to replace the wiring bonding is proposed, in which chips are connected to each other three-dimensionally with the shortest length of interconnection using through electrodes.

Examples of the related art include Japanese Patent No. 4005762 (Document 1) and Japanese Patent No. 3381601 (Document 2).

### SUMMARY

Having the structure described above, the distance between a semiconductor substrate for active elements and passive elements can be at least as large as the thickness of a substrate for the passive elements. Having such a distance, the influence of the semiconductor substrate on the passive elements can be reduced. However, connection portions (pads) are formed on the surface of the semiconductor substrate for active elements on which active elements are formed, to connect the semiconductor substrate to the substrate on which the passive elements are formed. It is therefore necessary to secure regions for the pads and also allow for margins of superimposition for the connection. As a result, the element formation region cannot be used effectively, and reduction in chip size has its limitations.

In view of the above, in an integrated circuit device in which a semiconductor substrate having active elements formed thereon and a substrate having passive elements formed thereon are connected to each other, a technique permitting effective use of the element formation region is described hereinafter.

The integrated circuit device of the present disclosure includes a first substrate and a second substrate, wherein the first substrate includes a semiconductor substrate, an active element is formed on one of the surfaces of the first substrate, and a first through electrode electrically connected to the active element is formed to extend through the first substrate, a passive element is formed on one of the surfaces of the second substrate, and a second through electrode electrically connected to the passive element is formed to extend through the second substrate, the other surface of the first substrate and the other surface of the second substrate are opposed to each other, and the first through electrode and the second through electrode are electrically connected to each other.

According to the integrated circuit device of the present disclosure, the first substrate and the second substrate are placed so that the surfaces (back surfaces) opposite to the element formation surfaces (surfaces on which the active element and the passive element are formed) face each other.

Therefore, as in the conventional configuration, the distance between the first substrate and the passive element formed on the second substrate can be at least as large as the thickness of the second substrate, and thus the influence of the first substrate on the passive element can be sufficiently reduced. Also, the distance between the active element formed on the first substrate and the passive element formed on the second substrate can be at least as large as the sum of the thickness of the first substrate and the thickness of the second substrate. Hence, since the inter-element distance (distance between the active element and the passive element) is increased by the thickness of the first substrate compared with the conventional case, the influence of the magnetic field generated by the passive element on the active element can be further reduced compared with the conventional case.

Also, on the element formation surfaces, only the minimum areas necessary for formation of the through electrodes are allocated for electrical connection between the active element on the first substrate and the passive element on the second substrate. Therefore, the element formation surfaces can be effectively used compared with the conventional configuration in which electrode pads must be placed on the element formation surfaces. This is advantageous for size reduction of the device.

Preferably, a back electrode is provided on at least one of the other surface of the first substrate and the other surface of the second substrate, and the first through electrode and the second through electrode are electrically connected to each other via the back electrode.

In other words, a back electrode is formed on the first substrate and electrically connected to the second through electrode, or a back electrode is formed on the second substrate and electrically connected to the first through electrode. Otherwise, back electrodes are formed on both the first substrate and the second substrate, and such back electrodes are electrically connected to each other.

The back electrode can be made large compared with the portion of the first through electrode exposed to the back surface of the first substrate and the portion of the second through electrode exposed to the back surface of the second substrate. Having such a back electrode, it is possible to reduce the precision of superimposition required at the electrical connection between the first through electrode and the second through electrode. Such a back electrode, which is placed on the back surface of the substrate, does not occupy the element formation surface and hence won't impede size reduction of the device.

The passive element is preferably an inductor.

When the passive element provided on the second substrate is an inductor, or a spiral inductor, in particular, the effect of increasing the distance of the passive element from the active element and the first substrate is remarkable.

The inductor is preferably made of a conductive material including at least one of Cu, Au, Ag, and Al.

The second substrate is preferably a semiconductor substrate, and the resistivity of the second substrate is preferably higher than the resistivity of the first substrate. Specific examples of the semiconductor substrate include a high-resistance Si substrate and a GaAs substrate.

The second substrate is preferably an insulating substrate.

Specific examples of the insulating substrate include insulating resin substrates (organic insulating substrates) made of polyimide, benzocyclobutane (BCB), epoxy, and the like. A quartz substrate, a ceramic substrate, and the like may also be used.

The first substrate and the second substrate are preferably electrically connected to each other via a bump.

The above configuration further increases the distance between the first substrate and the second substrate, permitting further reduction of the influence of the magnetic field generated by the passive element on the active element.

As the first through electrode and the second through electrode, those formed by filling connection holes formed through the first substrate and the second substrate with a conductive material can be used.

According to the integrated circuit device described above, in which the first substrate and the second substrate are electrically connected to each other with the back surfaces thereof opposed to each other, the element formation surfaces can be effectively used. Moreover, the distance between the active element and the passive element can be increased, permitting reduction in the influence of the magnetic field generated by the passive element on the active element. In particular, in a high-frequency domain, the parasitic capacitance can be minimized by securing a sufficient distance between the first substrate and the passive element, permitting improvement in the performance of the integrated circuit device.

### BRIEF DESCRIPTION OF THE DRAWINGS

FIG. 1 is a schematic cross-sectional view of a main portion of an example integrated circuit device of the first embodiment of the present disclosure.

FIG. 2 is a schematic plan view of a passive element of the example integrated circuit device of the first embodiment of the present disclosure.

FIGS. 3A-3E are views showing a process of forming an inductor and the like on a substrate for passive elements of the integrated circuit device of FIG. 1.

FIGS. 4A-4D are views showing, following FIG. 3E, the process of forming an inductor and the like on a substrate for passive elements of the integrated circuit device of FIG. 1.

FIGS. 5A-5D are views showing a process of forming an active element and the like on a substrate for active elements of the integrated circuit device of FIG. 1.

FIGS. 6A-6D are views showing, following FIG. 5D, the process of forming an active element and the like on a substrate for active elements of the integrated circuit device of FIG. 1.

FIG. 7 is a schematic cross-sectional view of a main portion of another example of the integrated circuit device of the first embodiment of the present disclosure.

FIG. 8 is a schematic cross-sectional view of a main portion of yet another example of the integrated circuit device of the first embodiment of the present disclosure.

FIG. 9 is a schematic cross-sectional view of a main portion of yet another example of the integrated circuit device of the first embodiment of the present disclosure.

FIG. 10 is a schematic cross-sectional view of a main portion of an example integrated circuit device of the second embodiment of the present disclosure.

FIGS. 11A-11E are views showing a process of forming an active element and the like on a substrate for active elements of the integrated circuit device of FIG. 10.

FIGS. 12A-12D are views showing, following FIG. 11E, the process of forming an active element and the like on a substrate for active elements of the integrated circuit device of FIG. 10.

FIG. 13 is a schematic cross-sectional view of a main portion of another example of the integrated circuit device of the second embodiment of the present disclosure.

### DETAILED DESCRIPTION

### First Embodiment

An example integrated circuit device 100 of the first embodiment will be described hereinafter with reference to the accompanying drawings.

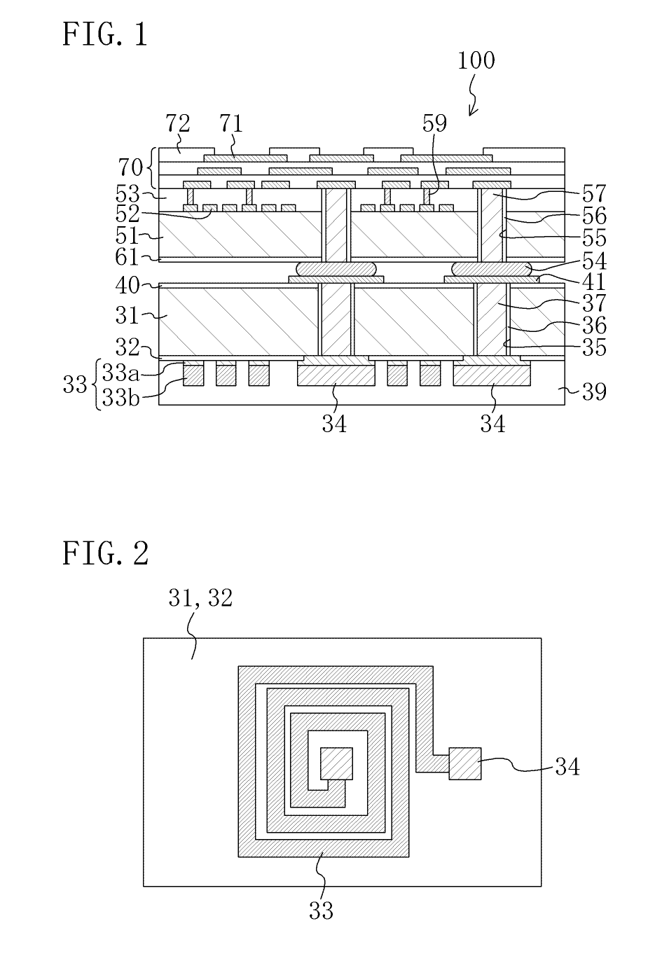

FIG. 1 is a cross-sectional view of a main portion of the integrated circuit device 100. The integrated circuit device 100 is a monolithic IC formed in the following manner: active element portions 52 such as metal oxide semiconductor (MOS) transistors are formed on one of two substrates (first substrate 51) while passive elements such as a spiral inductor 33 are formed on the other substrate (second substrate 31), and then the two substrates are connected to each other. Examples of the active element portions other than the MOS transistors include bipolar transistors, diodes, and the like, and examples of the passive elements other than the spiral inductor include resistances, capacitors, and the like.

The first substrate 51 for active elements is an n-type or p-type silicon substrate, on one surface (the element formation surface; the upper surface as viewed from FIG. 1) of which the active element portions 52 are formed. A first through electrode 57 is formed in each of through holes (connection holes) 55 via an insulating film 56, to extend through the first substrate 51. The active element portions 52 and the first through electrodes 57 are electrically connected to each other via a multilayer wiring layer 70 including interconnects 71 and insulating films 72.

The second substrate 31 for passive elements is an intrinsic silicon substrate high in resistivity (i.e., high in insulation properties) (high-resistance silicon substrate including little impurities). On one surface (the element formation surface; the lower surface as viewed from FIG. 1) of the second substrate 31, the spiral inductor 33 is formed via an insulating film 32. FIG. 2 shows a plan view of the spiral inductor 33. Terminals 34 are provided on both ends of the spiral inductor 33.

A second through electrode 37 is formed in each of through holes (connection holes) 35 via an insulating film 36, to extend through the second substrate 31 at a position immediately below each of the terminals 34 of the spiral inductor 33. On the surface (back surface) of the second substrate 31 opposite to the element formation surface thereof, formed are back electrodes 41 connected to the second through electrodes 37. That is, the terminals 34 of the spiral inductor 33 and the back electrodes 41 are electrically connected to each other via the second through electrodes 37.

The first substrate 51 and the second substrate 31 are placed so that the back surfaces thereof face each other. The portions of the first through electrodes 57 exposed to the back surface of the first substrate 51 and the back electrodes 41 placed on the back surface of the second substrate 31 are connected to each other via bumps 54. Accordingly, the active element portions 52 on the first substrate 51 and the spiral inductor 33 on the second substrate 31 are electrically connected to each other.

The spiral inductor 33, formed by electrolytic plating, includes a seed layer 33a made of Cu and a Cu film 33b formed on the seed layer 33a in the example of this embodiment. The spiral inductor 33 has a line width of 8 μm, an inter-line space of 2 μm, and a thickness of 5 μm, and is formed in a region of 500 μm square, in the illustrated example.

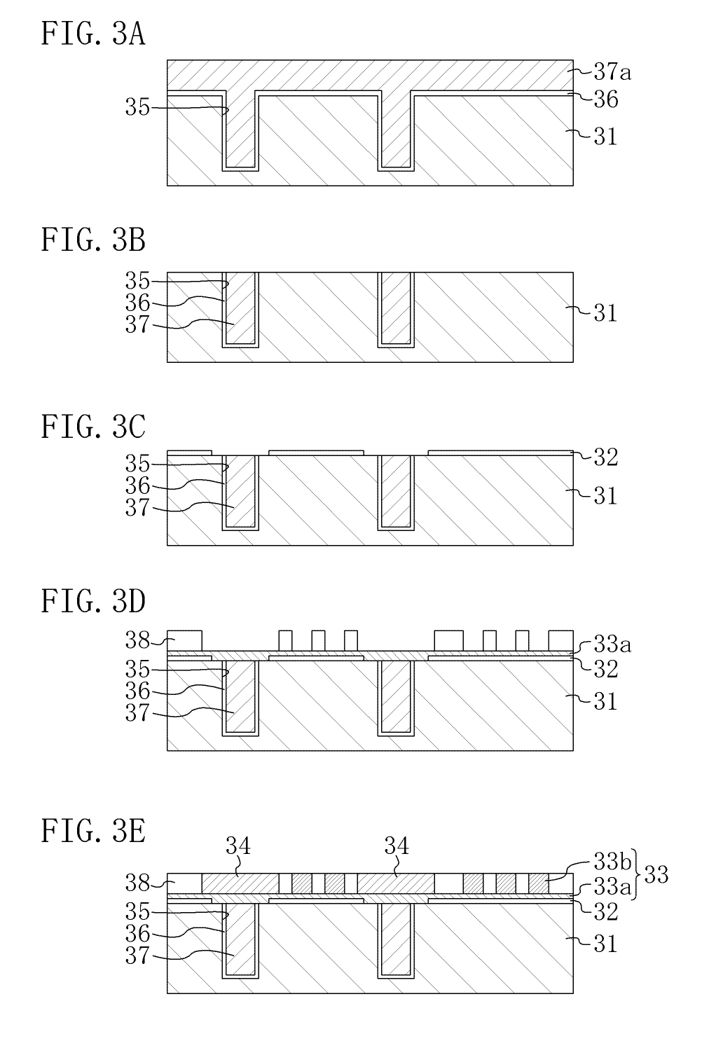

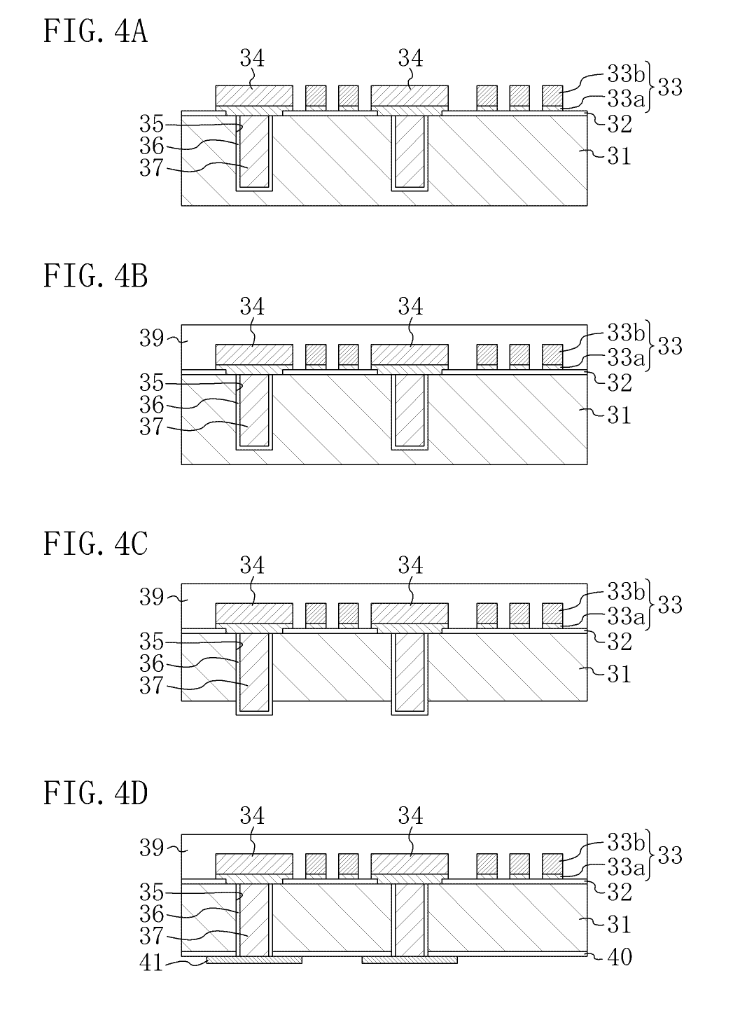

Next, a method for fabricating the integrated circuit device 100 (monolithic IC) shown in FIGS. 1 and 2 will be described. First, a process of forming the spiral inductor 33 and the like on the second substrate 31 for passive elements will be described with reference to FIGS. 3A-3E and 4A-4D.

As shown in FIG. 3A, the connection holes 35 having a depth of 50 to 300 μm and a diameter of 20 to 50 μm are formed on the second substrate 31 that is a high-resistance silicon substrate. The insulating film 36 is then formed to cover the inner surfaces of the connection holes 35 and the surface of the second substrate 31, and thereafter a metal film 37a is formed to cover the insulating film 36.

As shown in FIG. 3B, the portions of the metal film 37a and the insulating film 36 formed outside the connection holes 35 are removed by chemical mechanical polishing (CMP) while the portions thereof formed inside the connection holes 35 are left unremoved. The portions of the metal film 37a left behind inside the connection holes 35 serve as the second through electrodes 37.

A step shown in FIG. 3C is then performed, in which the insulating film 32 is first formed to cover the surface of the second substrate 31 including the surfaces of the second through electrodes 37, and then portions of the insulating film 32 located on the second through electrodes 37 and the surroundings thereof are selectively removed to expose the second through electrodes 37.

Subsequently, a metal film that is to be the spiral inductor 33 is formed in the following manner. Electrolytic plating is used in the illustrated example.

First, as shown in FIG. 3D, a Cu layer that is to be the seed layer 33a (feed portion) is formed by electroless plating to a thickness of about 0.1 μm to cover the underlying layers such as the insulating film 32 and the second through electrodes 37. In this formation, to improve the adherence of the seed layer 33a to the underlying layers, a barrier layer may be first formed to cover the underlying layers, and then the seed layer 33a may be formed on the barrier layer. As the barrier layer, Cr, Ni, Pt, and the like may be used. A resist 38 is then patterned on the seed layer 33a. The resist 38 is a planar pattern for formation of the spiral inductor 33 (including the terminals 34) shown in FIG. 2.

As shown in FIG. 3E, the Cu film 33b is formed on the seed layer 33a by immersing the resultant substrate in a plating solution and applying an electric field between the seed layer 33a and the plating solution. At this time, since no formation of the Cu film 33b is made on the portion of the seed layer 33a covered with the resist 38, the Cu film 33b is selectively formed on the portion of the seed layer 33a exposed between traces of the pattern of the resist 38. The terminals 34 are also formed as the same Cu film.

As shown in FIG. 4A, the resist 38 is removed with a remover solution, and then the portion of the seed layer 33a under the resist 38 is removed by wet etching. Note that, during this removal, the Cu film 33b may be more or less etched. In such a case, it is advisable to set the width and thickness of the Cu film 33b to values on the large side in advance. In this way, the spiral inductor 33 including the seed layer 33a and the Cu film 33b is formed.

Thereafter, as shown in FIG. 4B, a passivation film 39 is formed on the second substrate 31 to cover the spiral inductor 33.

The second substrate 31 is then polished from the back surface (surface opposite to the surface on which the spiral inductor 33 is formed) to expose the second through electrodes 37. In this polishing, the insulating film 36 covering the second through electrodes 37 may be left behind as shown in FIG. 4C, or may be removed to actually expose the second through electrodes 37, depending on the conditions of the polishing and the like. The influence of this difference is negligible.

Thereafter, as shown in FIG. 4D, the back electrodes 41 are formed at positions corresponding to the second through electrodes 37 in the following manner. An insulating film 40 is first formed to cover the entire back surface of the second substrate 31 including the exposed second through electrodes 37, and then polished to expose the second through electrodes 37. Subsequently, a metal film such as an aluminum film is formed on the back surface of the second substrate 31 and then patterned by photolithography, to form the back electrodes 41 connected to the second through electrodes 37. The back electrodes 41 should be formed to have a size and a shape with which they are kept from contact with each other.

Note that, double-sided alignment is adopted in the illustrated example, in which the back-surface mask pattern of the second substrate 31 is formed based on the surface pattern of the second substrate 31. Note also that copper, gold, and the like can also be used, in place of aluminum, as the material of the back electrodes 41.

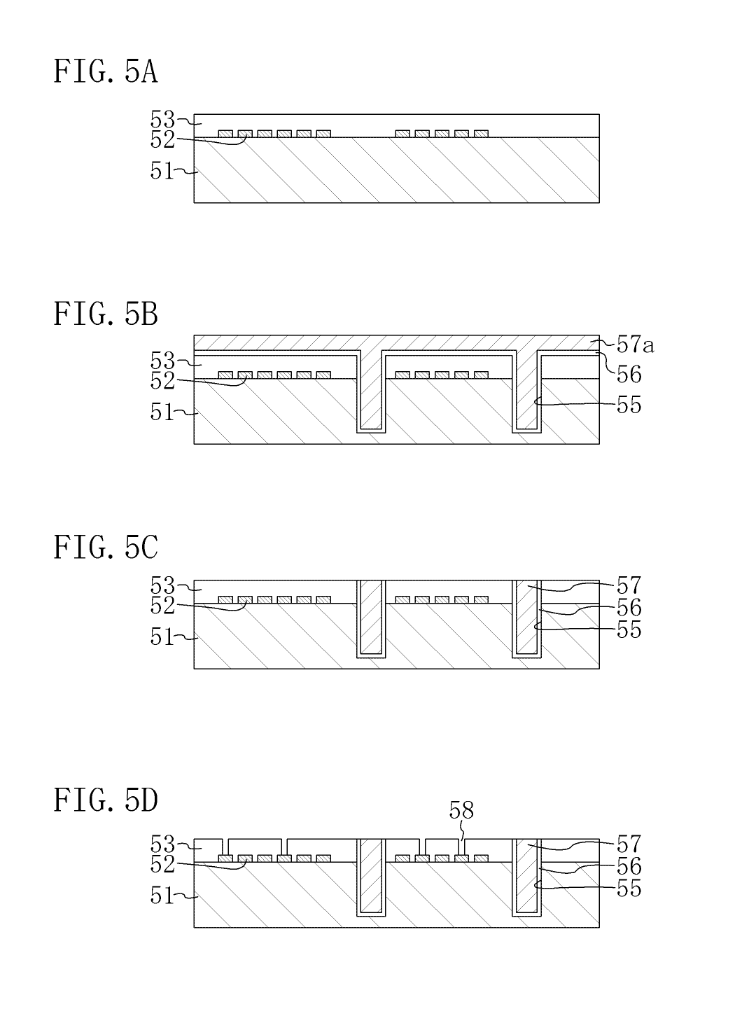

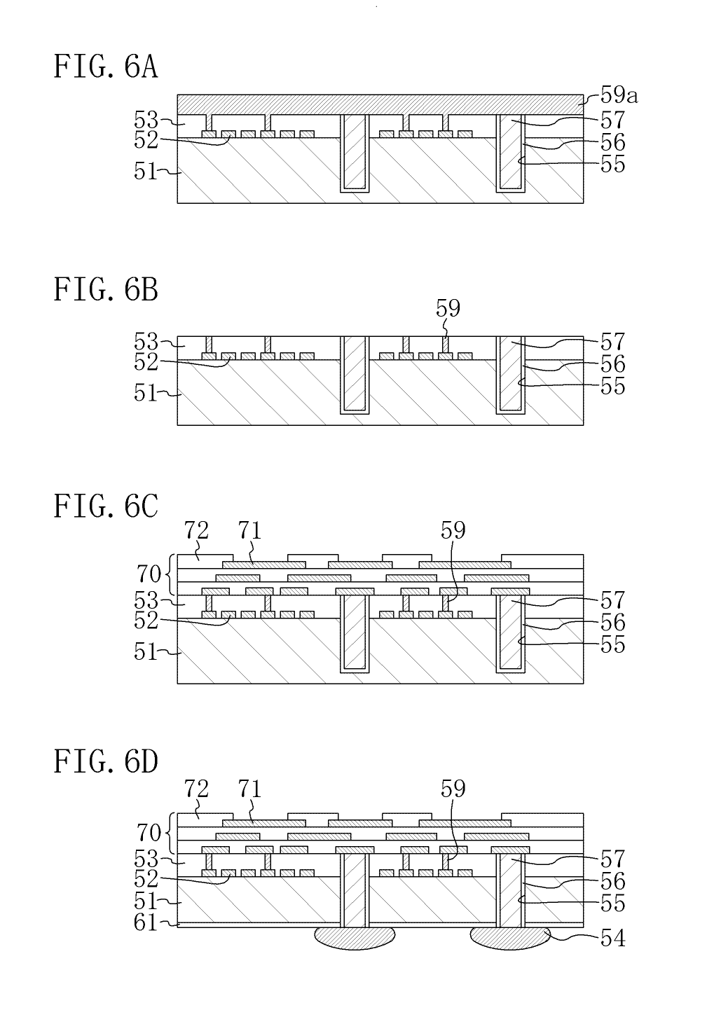

Next, a process of forming the first through electrodes 57 and the like on the first substrate 51 for active elements will be described with reference to FIGS. 5A-5D and 6A-6D.

As shown in FIG. 5A, the predetermined active element portions 52 are formed on the first substrate 51 for active elements, and then the insulating film 53 is formed to cover the active element portions 52.

As shown in FIG. 5B, the connection holes 55 having a depth of 50 to 300 μm and a diameter of 20 to 50 μm are formed on the first substrate 51 through the insulating film 53. The insulating film 56 is then formed on the entire surface of the first substrate 51 including the inner surfaces of the connection holes 55. Thereafter a metal film 57a is formed on the entire surface of the insulating film 56 including the inside of the connection holes 55.

As shown in FIG. 5C, the portions of the metal film 57a and the insulating film 56 formed outside the connection holes 55 are removed by CMP while the portions thereof formed inside the connection holes 55 are left unremoved. The portions of the metal film 57a left behind inside the connection holes 55 serve as the first through electrodes 57.

As shown in FIG. 5D, connection holes 58 are formed through the insulating film 53 for connection to the active element portions 52. Subsequently, as shown in FIG. 6A, a metal film 59a is formed to fill the connection holes 58 and cover the insulating film 53.

As shown in FIG. 6B, the portion of the metal film 59a formed outside the connection holes 58 is removed by CMP while the portions thereof inside the connection holes 58 are left unremoved. The portions of the metal film 59a inside the connection holes 58 serve as contact plugs 59 for securing electrical connection to the active element portions 52.

As shown in FIG. 6C, the multilayer wiring layer 70 including a plurality of interconnects 71 and insulating films 72 is formed. The active element portions 52 and the first through electrodes 57 are electrically connected to each other via the multilayer wiring layer 70.

As shown in FIG. 6D, the first substrate 51 is then polished from the back surface (surface opposite to the surface on which the active element portions 52 are formed) to expose the first through electrodes 57. Thereafter, an insulating film 61 is formed on the entire back surface of the first substrate 51 and then polished to expose the first through electrodes 57. Subsequently, the bumps 54 made of solder are formed on the exposed portions of the first through electrodes 57 on the back surface of the first substrate 51.

The individual processes of forming the first substrate 51 for active elements and the second substrate 31 for passive elements are thus completed. The first and second substrates 51 and 31 are then combined to implement the integrated circuit device 100 in the manner described below.

The first substrate 51 and the second substrate 31 are positioned so that the back surfaces thereof face each other and aligned. More specifically, images of the connecting surfaces are superimposed on each other using a split mirror to perform accurate XYθ alignment. Thereafter, the bumps 54 formed on the first through electrodes 57 of the first substrate 51 are connected to the back electrodes 41 formed on the second substrate 31 by pressure bonding. In this way, the integrated circuit device 100 as a monolithic IC shown in FIGS. 1 and 2 is completed.

As described above, in the integrated circuit device 100, the surfaces opposite to the element formation surfaces of the first substrate 51 and the second substrate 31 are opposed to each other for electrical connection. Therefore, large connection portions can be secured, and thus the precision of superimposition required at the connection is comparatively low. As for the element formation surfaces, effective use thereof is attainable because only the minimum areas necessary for formation of the first through electrodes 57 and the second through electrodes 37 are required.

Also, the distance between the passive elements (the spiral inductor 33 and the like) and the active elements (the active element portions 52) can be at least as large as the sum of the thickness of the first substrate 51 for active elements and the thickness of the second substrate 31 for passive elements. Moreover, as shown in FIG. 1, the thicknesses of the back electrodes 41 and the bumps 54 are also added to the distance between the active elements and the passive elements. Accordingly, the distance between the active and passive elements is increased, compared with the conventional structure, by the equivalent of the thickness of the first substrate 51 for active elements. As a result, the influence of the magnetic field generated by the passive elements on the active elements can be reduced compared with the conventional structure.

In addition, in a high-frequency domain, by securing a sufficient distance between the first substrate 51 on which the active element portions 52 are formed and the spiral inductor 33, the parasitic capacitance generated between the first substrate 51 and the spiral inductor 33 can be minimized. This can further improve the performance of the integrated circuit device 100.

In a device operating in a high-frequency domain, it is desirable that the capacitance between the sets of the bumps 54 and the back electrodes 41 and the first substrate 51 for active elements is as small as possible. Accordingly, the sizes of the bumps 54 and the back electrodes 41 should not be larger than required.

Although the bumps 54 are formed on the first substrate 51 for active elements in the illustrated example, they may be formed on the second substrate 31 for passive elements. Otherwise, the bumps 54 may be formed on both the first substrate 51 and the second substrate 31. Another connection method is proposed in which a substrate with bumps attached thereto is pressed against a substrate with a resin adhesive applied thereto for connection of the two substrates (see Document 2, for example).

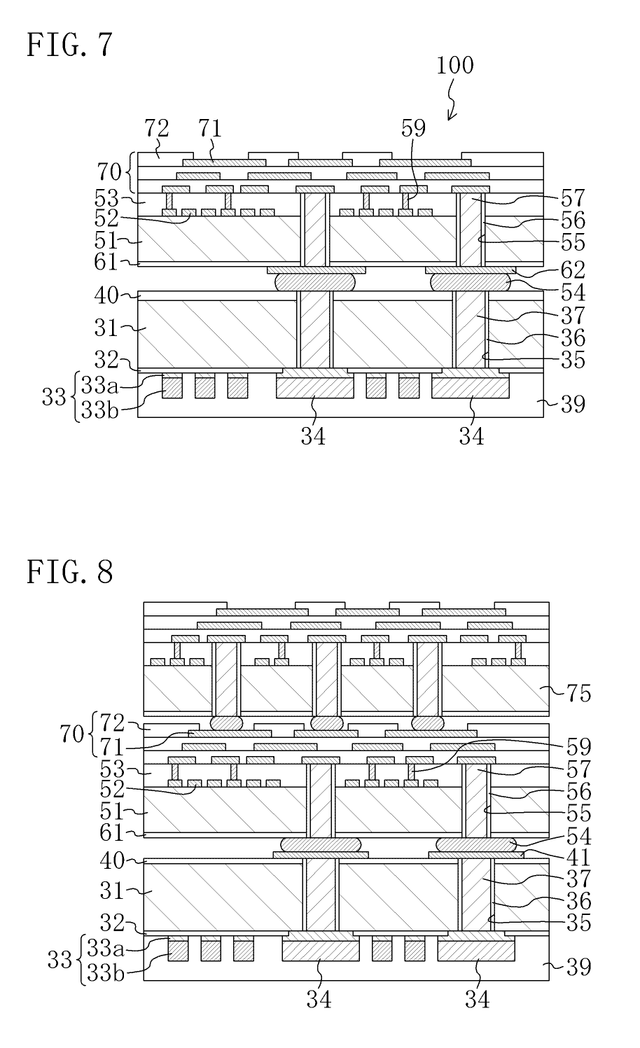

Although the back electrodes 41 are formed on the second substrate 31 for passive elements in the illustrated example (see FIG. 1), they may be formed on the first substrate 51 for active elements as shown in FIG. 7. FIG. 7 is the same as FIG. 1 except that back electrodes 62 are formed on the first substrate 51.

Employing the technique described above, a plurality of substrates can be stacked with through electrodes and bumps as shown in FIG. 8. More specifically, like the first substrate 51, active elements, through electrodes, a multilayer wiring layer, and the like are formed on a third substrate 75, and the portions of the through electrodes exposed to the back surface of the third substrate 75 are connected to the multilayer wiring layer 70 of the first substrate 51.

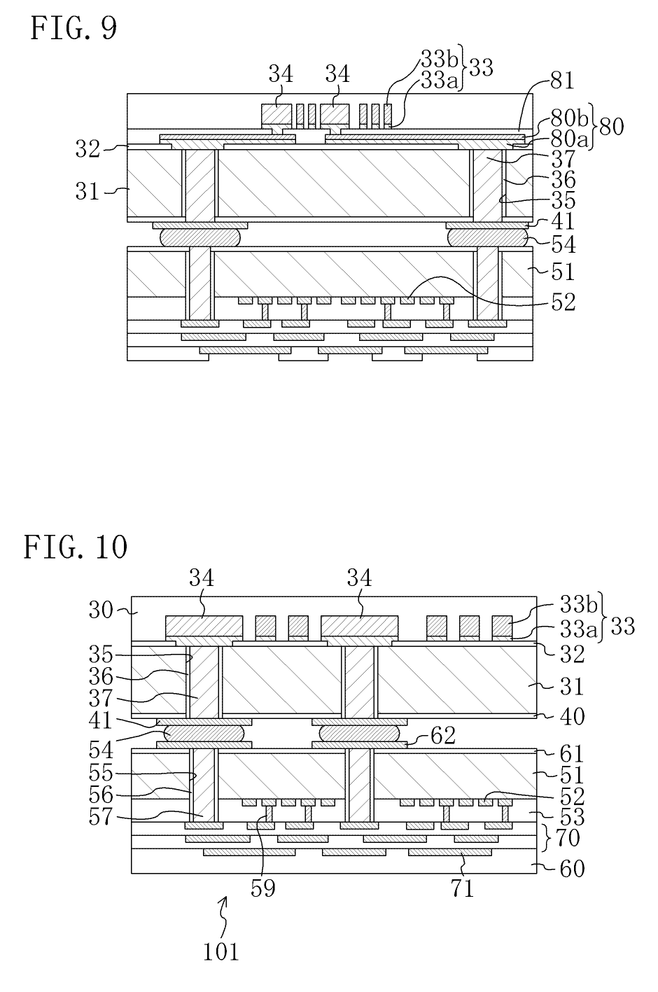

Although the second through electrodes 37 are placed at positions corresponding to the terminals 34 of the spiral inductor 33 in the illustrated example, the placement is not limited to this. As shown in FIG. 9, the terminals 34 may be placed at positions different from the second through electrodes 37 by forming interconnects 80 extending from the second through electrodes 37 to the corresponding terminals 34. Note that in FIG. 9 the second substrate 31 for passive elements is shown as the upper part. The interconnects 80, each made of a seed layer 80a and a Cu film 80b, are formed by plating like the spiral inductor 33. An insulating film 81 is formed to cover the interconnects 80.

With the placement described above, it is possible increase the size of the back electrodes 41 compared with the case of FIG. 1. In other words, while the size of the back electrodes 41 depends on the distance between the terminals 34 at both ends of the spiral inductor 33 in the configuration of FIG. 1, the configuration of FIG. 9 is free from such a limitation. Having such large back electrodes 41, the margin of superimposition between the first substrate 51 and the second substrate 31 increases. Also, this configuration makes it possible to use the structure of this embodiment even if the region of the spiral inductor 33 itself is small.

### Second Embodiment

An example integrated circuit device 101 of the second embodiment of the present disclosure will be described with reference to the relevant drawings. FIG. 10 is a cross-sectional view of a main portion of the integrated circuit device 101. Unlike the first embodiment in which the back electrodes are formed on only one of the first substrate 51 and the second substrate 31, the integrated circuit device 101 of this embodiment has back electrodes 62 and 41 respectively formed on the first and second substrates. This eases the requirements of precision of alignment and the like compared with the case of forming the bumps on the through electrodes. Also, the back electrodes can be used as pads.

Note that while the second substrate 31 for passive elements is shown as the lower part and the first substrate 51 as the upper part in FIG. 1, they are shown in reverse in FIG. 10, that is, the first substrate 51 is shown as the lower part and the second substrate 31 as the upper part.

Next, a method for fabricating the integrated circuit device 101 shown in FIG. 10 will be described.

The process of forming a spiral inductor 33 and the like on the second substrate 31 for passive elements is the same as that described in the first embodiment.

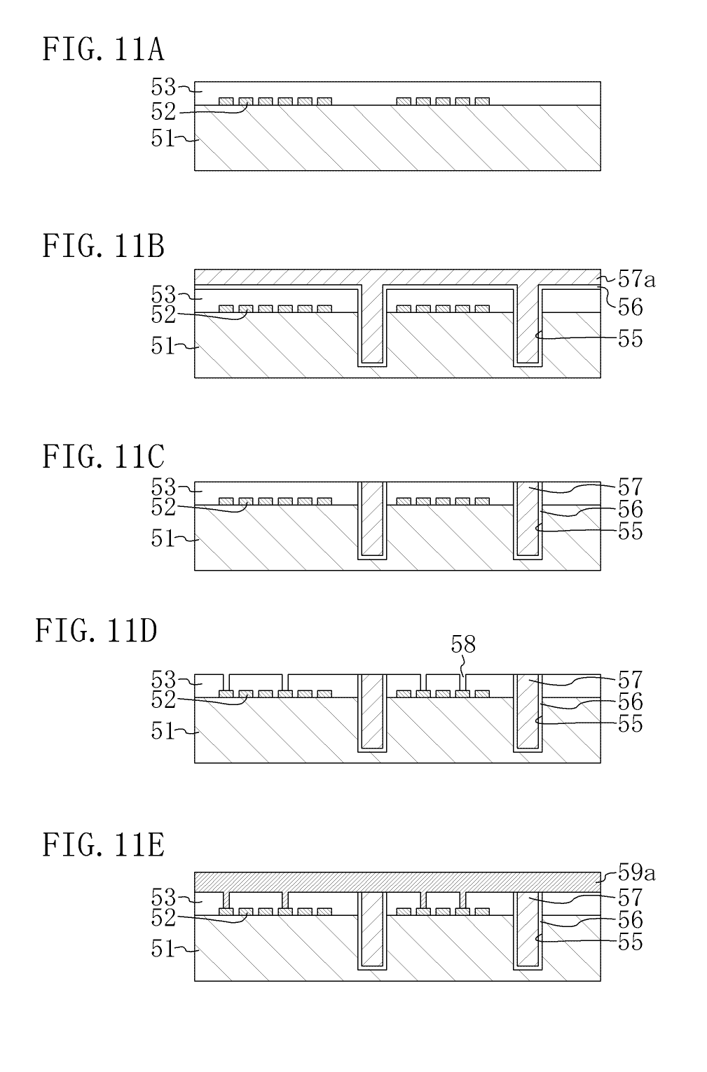

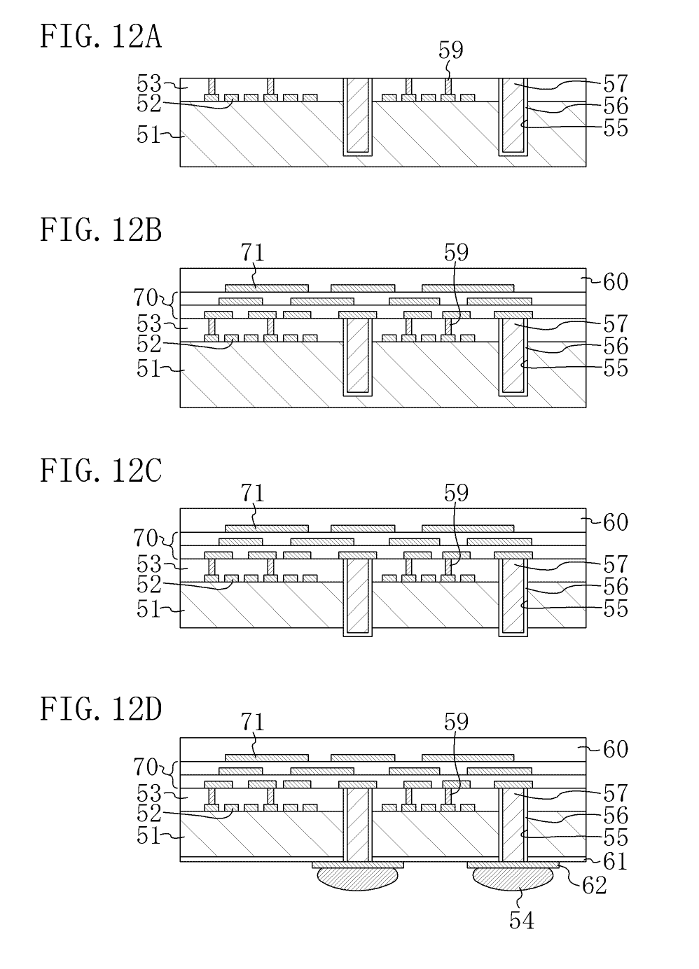

A process of forming first through electrodes 57 and the like on the first substrate 51 for active elements will be described with reference to FIGS. 11A-11E and 12A-12D.

As shown in FIG. 11A, predetermined active element portions 52 are formed on the first substrate 51 for active elements, and then an insulating film 53 is formed to cover the active element portions 52. As shown in FIG. 11B, connection holes 55 having a depth of 50 to 300 μm and a diameter of 20 to 50 μm are formed on the first substrate 51 through the insulating film 53. An insulating film 56 is then formed on the entire surface of the first substrate 51 including the inner surfaces of the connection holes 55, and thereafter a metal film 57a is formed on the entire surface of the insulating film 56 including the inside of the connection holes 55.

As shown in FIG. 11C, the portions of the metal film 57a and the insulating film 56 formed outside the connection holes 55 are removed by CMP while the portions thereof formed inside the connection holes 55 are left unremoved. The portions of the metal film 57a left behind inside the connection holes 55 serve as the first through electrodes 57.

As shown in FIG. 11D, connection holes 58 are formed through the insulating film 53 for connection to the active element portions 52. Subsequently, as shown in FIG. 11E, a metal film 59a is formed to fill the connection holes 58 and cover the insulating film 53.

As shown in FIG. 12A, the portion of the metal film 59a formed outside the connection holes 58 is removed by CMP while the portion thereof inside the connection holes 58 is left unremoved. The portions of the metal film 59a inside the connection holes 58 serve as contact plugs 59 for securing electrical connection to the active element portions 52.

As shown in FIG. 12B, a multilayer wiring layer 70 is formed, through which the active element portions 52 and the first through electrodes 57 are electrically connected to each other. A passivation film 60 is then formed to cover the multilayer wiring layer 70.

As shown in FIG. 12C, the first substrate 51 is then polished from the back surface to expose the first through electrodes 57. Thereafter, as shown in FIG. 12D, an insulating film 61 is formed on the entire back surface of the first substrate 51 and then polished to expose the first through electrodes 57. Subsequently, a metal film such as aluminum is formed on the entire back surface of the first substrate 51 to cover the first through electrodes 57 and the insulating film 61 and then patterned by photolithography to form the back electrodes 62.

Note that double-sided alignment is adopted in the illustrated example, in which the back mask pattern for the first substrate 51 is formed based on the surface pattern of the first substrate 51 as a silicon substrate.

Although aluminum is used as the material of the back electrodes 62 in this embodiment, other materials such as copper, gold, and the like may be used.

If the first substrate 51 and the second substrate 31 are misaligned, adjacent back electrodes 62, for example, may possibly be electrically connected (short-circuited) to each other via a back electrode 41, depending on the sizes of the back electrodes 41 and 62. Therefore, the back electrodes 41 and 62 are formed to have a size and a shape with which such an occurrence can be avoided.

After the formation of the back electrodes 62, bumps 54 made of solder are formed on the back electrodes 62. In this way, the process of forming the first substrate 51 for active elements is completed.

Thereafter, the first substrate 51 and the second substrate 31 are positioned so that the back surfaces thereof face each other to perform alignment as in the first embodiment. The bumps 54 formed on the back electrodes 62 of the first substrate 51 are connected to the back electrodes 41 formed on the second substrate 31 by pressure bonding. In this way, the integrated circuit device 101 as a monolithic IC is completed.

In the integrated circuit device 101 of this embodiment, also, the first substrate 51 and the second substrate 31 are electrically connected so that the back surfaces thereof are opposed to each other. Therefore, effects similar to those obtained in the first embodiment are obtained. More specifically, the precision of superimposition required at the connection of the substrates is comparatively low, and the element formation surfaces can be used effectively. Also, the influence of the magnetic field generated by the passive elements on the active elements can be reduced compared with the conventional structure.

In addition, as in the first embodiment, in a high-frequency domain, a sufficient distance can be secured between the first substrate 51 and the spiral inductor 33, permitting minimization of the parasitic capacitance. Also, to reduce the capacitance between the sets of the bumps 54 and the back electrodes 41 and the first substrate 51, the sizes of the bumps and the back electrodes should not be larger than required.

Although the bumps 54 are formed on the first substrate 51 for active elements in the illustrated example, they may be formed on the second substrate 31 for passive elements. Otherwise, the bumps 54 may be formed on both substrates. In this embodiment, also, a connection method using a resin adhesive, as proposed in Document 2, may be employed. Also, the terminals 34 may be placed at positions different from the second through electrodes 37 by forming interconnects extending from the second through electrodes 37 to the corresponding terminals 34.

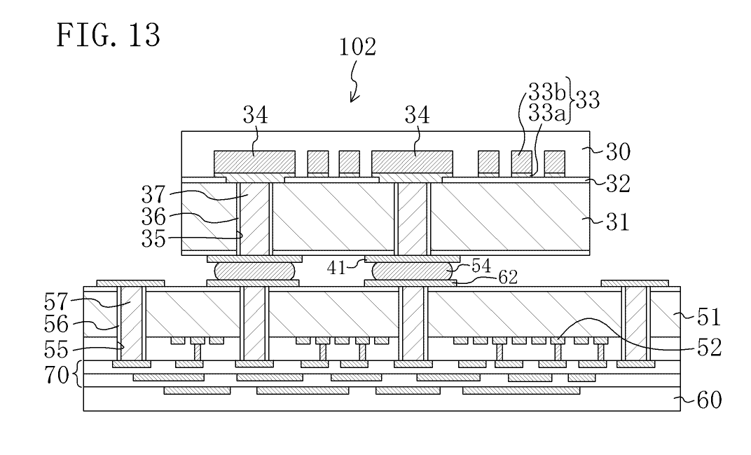

As an example of using the back electrodes 62 as pads, an integrated circuit device 102 is shown in FIG. 13. While the first substrate 51 and the second substrate 31 have the same size (same width in the illustrated example) in the integrated circuit device 101 of FIG. 10, the first substrate 51 is larger than the second substrate 31 in the integrated circuit device 102. On the portion of the first substrate 51 protruding beyond the periphery of the second substrate 31, formed are first through electrodes 57 different from the first through electrodes 57 for connection to the second substrate 31, together with back electrodes 62, to be used as pads for electrically connecting the integrated circuit device 102 to another device.

Although the inductor having a square spiral shape was described in the first and second embodiments, the inductor is not limited to this shape, but may be of a triangle, a polygon having five or more sides, a circle, and the like. Although the dual damascene technique was described as the inductor formation method, the method is not limited to this, but another formation method may be employed. Although the first substrate 51 and the second substrate 31 are connected with only bumps in the first and second embodiments, the strength can be enhanced by filling the space between the substrates with an insulating adhesive. Further changes falling within the spirit and scope of the present application can be made to particulars such as the number of turns of the spiral inductor 33.

As described above, according to the technique of the present disclosure, in an integrated circuit device in which a substrate having active elements formed thereon and a substrate having passive elements formed thereon are connected to each other via an appropriate means, high precision of superimposition is not required and the element formation regions of the surfaces can be effectively used. Therefore, the present disclosure is useful in an integrated circuit device having a plurality of chips stacked three-dimensionally.

What is claimed is:

1. An integrated circuit device, comprising:
a first substrate; and
a second substrate,
wherein
the first substrate includes a semiconductor substrate,
an active element is formed on one of the surfaces of the first substrate, and a first through electrode electrically connected to the active element is formed to extend through the first substrate,
a passive element is formed on one of the surfaces of the second substrate, and a second through electrode electrically connected to the passive element is formed to extend through the second substrate,
the other surface of the first substrate and the other surface of the second substrate are opposed to each other, and
the first through electrode and the second through electrode are electrically connected to each other.

2. The integrated circuit device of claim 1, wherein
a back electrode is provided on at least one of the other surface of the first substrate and the other surface of the second substrate, and
the first through electrode and the second through electrode are electrically connected to each other via the back electrode.

3. The integrated circuit device of claim 1, wherein
the passive element is an inductor.

4. The integrated circuit device of claim 3, wherein
the inductor is made of a conductive material including at least one of Cu, Au, Ag, and Al.

5. The integrated circuit device of claim 1, wherein
the second substrate is a semiconductor substrate.

6. The integrated circuit device of claim 5, wherein
the resistivity of the second substrate is higher than the resistivity of the first substrate.

7. The integrated circuit device of claim 1, wherein
the second substrate is an insulating substrate.

8. The integrated circuit device of claim 1, wherein
the first substrate and the second substrate are electrically connected to each other via a bump.
